(19) United States
(12) Patent Application Publication
(10) Pub. No.: US 2024/0158908 A1
(43) Pub. Date: May 16, 2024

(54) COATING SYSTEM FOR COATING A STRIP AND METHOD FOR COATING A STRIP

(71) Applicant: ThyssenKrupp Steel Europe AG, Duisburg (DE)

(72) Inventors: Janine-Christina SCHAUER-PASS, Dorsten (DE); Michael STRACK, Recklinghausen (DE)

(21) Appl. No.: 18/280,546

(22) PCT Filed: Jan. 27, 2022
(86) PCT No.: PCT/EP2022/051904

§ 371 Date: Sep. 6, 2023

(30) Foreign Application Priority Data
Apr. 23, 2021 (DE) 10 2021 110 394.0

(51) Int. Cl. C23C 14/56; B65H 23/00; C23C 14/24; C23C 14/50; C23C 14/54

(52) U.S. Cl. CPC C23C 14/562; B65H 23/00; C23C 14/24; C23C 14/50; C23C 14/545; B65H 2404/14

(57) ABSTRACT

A coating system for coating a strip, for example a steel strip, with a material present in the gas phase includes a coating chamber, a device for vapor deposition of the material, and a strip positioning assembly for correcting the strip transport. The strip positioning assembly has a first guide roller and a second guide roller pivoting about a pivot point, which can be effected with an adjustment unit. A method for coating a strip is also provided.

The invention relates to a coating system for coating a strip. The invention also relates to a method for coating a strip.

Methods which are based on the principle of so-called vapor deposition can be used for coating a strip, in particular a metal strip, such as, for example, a steel strip. The principle of vapor deposition is to provide a starting material and convert it into the gas phase. The components of the material, in particular atoms and/or ions, present in the gas phase move within a coating chamber and are guided to a region in which the coating is to take place, which is referred to below as the coating zone. The strip is transported through the coating zone so that the components of the material in the gas phase settle on the strip to be coated and thereby form a coating.

An advantage of vapor deposition is that coatings can be produced quite economically whose properties can be specifically influenced to a high degree and within wide property windows. Another advantage is that vapor deposition is suitable for producing coatings of many different materials. In contrast to some other methods, vapor deposition is suitable for example for the production of coatings with a high-melting material or coatings with material in a metastable phase or in metastable phases.

The present invention is associated with a device for the vapor deposition of material, wherein the material converted into the gas phase is directed to the coating zone through a nozzle outlet of a nozzle section of the device for vapor deposition of material.

The strip is guided past a device for vapor deposition within a coating chamber and coated with components present in the gas phase emerging therefrom. Here it is desirable to apply the coating as homogeneously as possible, i.e. in particular with homogeneous thickness, not only in the longitudinal direction of the strip but also in the transverse direction of the strip. Against the background that not only strip transportation itself is subject to fluctuations but also, depending on the specific conditions of the coating (material, geometry of the nozzle, etc.), homogeneity of the movement of the materials present in the gas phase can vary, the object of the present invention is to achieve improved homogeneity of the coating.

The object is achieved with a coating system having the features of claim 1 and with a method for coating a strip having the features of claim 13.

The coating system should also serve to enable a strip to be coated and for this purpose comprises the following components:

The coating system has a coating chamber. The coating chamber has a chamber inlet and a chamber outlet, wherein the strip to be coated is guided into the chamber inlet, through the chamber, and out of the chamber outlet. The coating chamber is typically a largely closed chamber in which a technical vacuum can preferably be provided, for example between 10⁽⁻³⁾ mbar and 100 mbar, preferably with less than 20 mbar.

The coating chamber further comprises a device for vapor deposition of the material. The device for vapor deposition comprises an evaporation section in which the material originally provided as a starting material is evaporated into the gas phase, and a nozzle section with which the material then present in the gas phase is directed towards the strip surface to be coated so that the particles of the gas phase flowing out of a nozzle outlet of the nozzle section flow towards the coating zone.

The starting material can be evaporated in any known manner, for example by means of thermal evaporation, arc evaporation as well as others and combinations of the aforementioned. It is essential in the context of the present invention for the material, after passing through the evaporation section, to be in the gas phase and then be guided in a directed manner by the nozzle section to the strip surface which is to be coated, and to condense thereon when the strip surface is reached.

The strip passes through the coating zone which is a region in which the material present in the gas phase contacts the strip being continuously transported through the coating chamber. The strip is therefore continuously exposed to the material in the gas phase so that, as a result of the continuous movement of the strip in the course of its transport through the chamber, the desired coating is formed on the strip surface as a result of condensation of the material in the gas phase.

Optionally, a coating channel can be arranged within the coating chamber and equipped with heating means for heating, and through which the strip is transported at least in the region of the coating zone.

Throughout the entire description, the terms “gas phase” and “evaporation” are used as commonly in use in technologies in the field of vapor deposition. The term gas phase in this case includes the fact that a low weight fraction, for example up to 30 percent by weight, preferably not more than 10 percent by weight, of the material present in the gas phase is not present in a strictly physical sense, but instead is present as a vapor, as an aerosol and/or as a cluster. The term evaporation includes the fact that, depending on the employed material and the employed technology, the particles transition into the gas phase at least partially also by means of mechanisms other than evaporation in a strictly physical sense, for example by sublimation. In the context of linguistic usage in the field of vapor deposition, and therefore in the context of the present description, the term evaporation therefore also includes other mechanisms, such as sublimation in particular, in addition to evaporation in the strictly physical sense, i.e. a liquid→gas phase transition. Likewise, the material present in the gas phase is therefore also referred to synonymously as a material vapor.

Viewed in the strip transport direction, a strip positioning assembly is arranged in front of the coating zone. The strip positioning assembly serves the purpose of contributing to a continuous correction of strip transportation. For this purpose, the strip positioning assembly has at least one first guide roller arranged on the first side of the strip, and a second guide roller arranged on the second side of the strip. The first guide roller and the second guide roller are positioned such that, during transportation of the strip, not only the first guide roller but also the second guide roller are in contact with the strip, namely the first guide roller with the first strip surface, and the second guide roller with the second strip surface.

A strip positioning assembly, which has two guide rollers which are positioned in front of the coating zone and both preferably in contact with the strip surface, causes the strip guidance of the strip to be subjected to a correction immediately before the strip surface is coated with the material vapor. After passing through the positioning assembly, the strip is closer to a exemplary and ideal strip run than before. In particular, the transverse curvature of the strip is closer to a desired state; preferably the transverse curvature is reduced and particularly preferably eliminated. The term transverse curvature is known in the technical field of strip transport. It designates a deviation of the strip from the ideal strip plane in the form of a curvature in the cross-section of the strip in the direction perpendicular to the transport direction. For this reason, if the surfaces of the strip do not form straight lines, but rather arced curves in cross-section, a transverse curvature will be present. The aim is to minimize or completely eliminate the transverse curvature, this being achieved with the coating system according to the invention and its further developments. The procedure according to the invention advantageously ensures that the strip in the coating zone is subject to smaller fluctuations in transverse curvature during the entire coating period, with the result that the coating is more homogeneous not only in the longitudinal direction of the strip but also in the transverse direction of the strip as compared to a coating carried out without a positioning assembly.

This means that the correction of strip transportation comprises at least the correction of the transverse curvature, that is, the reduction or the elimination of the transverse curvature. The correction of the transverse curvature is achieved by the guide rollers which are arranged on both sides of the strip and are in contact with the strip, i.e. the first guide roller and the second guide roller.

Preferably, the axis of rotation of one of the two guide rollers is fixed or is configured to be continuously fixed during strip transportation, and the axis of rotation of the other of the two guide rollers at the point of contact of the roller lateral face with the strip is movable in a direction perpendicular to the strip surface, or is movable in a direction having a directional component perpendicular to the strip surface. This means that the position of the guide roller in the direction perpendicular to the strip surface can be changed so that the still rotatable guide roller, depending on the selected position of the axis of rotation, influences the guidance of the strip in different ways, for example by moving the axis of rotation in the direction facing the strip manifested as bringing about a slight deflection. The deflection is achieved in that, as seen from a top view of the strip positioning assembly in the strip transport direction, the lower edge of the first guide roller is below the upper edge of the second guide roller when the first guide roller is considered the upper guide roller, regardless of its actual positioning in space. This movement of the axis of rotation in a direction perpendicular to the strip surface can be achieved, for example, by means of an adjustment unit designed to be vacuum-compatible and arranged inside the coating chamber, wherein adjustment units known to the specialist which are electrical or pneumatic or in mixed forms can be provided. Alternatively, a mechanism located outside the coating chamber can also be arranged on the coating system for movement perpendicular to the strip surface, wherein an entry point of a device bringing about the movement, for example a metal rod, is designed for example as a lead-through into the vacuum chamber, wherein the lead-through is preferably implemented vacuum-tight by means of a bellows.

For example, it can be provided that the guide roller which is present on the side of the nozzle outlet is fixed, and the roller of the strip opposite the nozzle outlet is designed as a roller which is movable perpendicular to the strip surface. It is particularly advantageous to have an embodiment in which the movement relative to the strip surface has a degree of freedom such that a movement of the guide roller movable perpendicular to the strip surface exerts a pressure perpendicular to the surface on the surface of the strip in combination with a counterpressure caused by the stationary roller. By such an arrangement, it can be achieved that, by exerting pressure by increasing a deflection of the movable roller in the direction of the strip surface, an increasing application of force on the surface along a line of contact on the lateral face of the guide roller lengthwise to the axis of rotation of the guide roller is applied to the strip. This has the effect that the strip aligns itself in its transverse direction with the profile of the movably arranged roller. For example, in a preferred case in which the roller has a circular-cylindrical arc of the lateral face, any transverse arc that may be present, that is, a deviation of the transverse profile of the strip from a straight line, can be compensated or at least partially compensated. The fact that the guide roller, which can be moved perpendicular to the strip surface, rotates with the strip movement means that this corrective action can be carried out during the entire coating process and—if desired—along the entire length of the strip so that, after the coating process, a strip exists whose coating has excellent homogeneity in every direction lying on the strip surface.

Due to the fact that a relative movement of the movable guide roller relative to the stationary guide roller is possible, it is possible for a force acting perpendicular to the strip surface to be achievable with comparatively uncomplicated means, namely by providing only one movable roller.

A minimum application of force by the movable roller is given, for example, in a preferred basic position in which the lateral face of the movable guide roller and the lateral face of the fixed guide roller have tangential planes parallel to each other and parallel to the strip surfaces, the distance between which corresponds to the thickness of the strip. According to this further development, the movability of the other of the two guide rollers is preferably implemented in such a way that the movable roller is mounted movably from this described basic position in the direction of the half-space in which the non-movable roller is located; or in other words, the axis of rotation of the movable roller is movable in a direction perpendicular to the strip surface in such a way that the strip is forced into a deflection path. This is achieved by, geometrically speaking, moving the plane parallel to the strip surface of the undeformed strip, which contains the axis of rotation of the movable guide roller, in the direction of the plane parallel to the undeformed strip surface which contains the axis of rotation of the fixed axis of rotation, in such a way that the distance between these two planes becomes smaller than the sum of the two radii of the two guide rollers plus the strip thickness. With increasing movement of the axis of rotation of the movable guide roller in the described direction, this distance decreases, being accompanied by an increase in the force acting on the strip surface which in turn allows increasing elimination of any existing transverse arcs. This mechanism is a preferred variant of the strip positioning assembly with which removal or reduction of transverse arcs in the strip to be coated can be achieved in a comparatively uncomplicated manner.

It is particularly preferred if the first guide roller and the second guide roller, when viewed in the strip transport direction, are arranged at a distance from each other in the coating system, i.e., such that the two lines of contact with the strip formed by the guide rollers are spaced apart from each other when viewed in the strip transport direction. In this way, the guidance of the strip can be influenced in a particularly advantageous manner such that a transverse arc of the strip can be eliminated or at least reduced so that ultimately, there is neither a concave transverse arc nor a convex transverse arc, in each case viewed from the nozzle outlet, or the respective transverse arc can be reduced at least compared to its magnitude before the positioning assembly.

It is preferred if the strip positioning assembly is arranged directly before the coating zone. This preferably means that the coating zone begins at most 11 meters, particularly preferably at most 4 meters, after the strip positioning assembly. The positioning of the strip positioning assembly immediately before the coating zone ensures that strip positioning brought about for the purpose of coating is still completely or at least almost completely preserved by reducing or eliminating transverse arcs at the site of coating.

According to an advantageous development, provision is made for a layer thickness sensor to be arranged behind the coating zone as viewed in the strip transport direction, which layer thickness sensor is suitable for a contactless determination of layer thickness values of the previously applied coating. For this purpose, the sensor is directed toward the coating, preferably in a perpendicular viewing direction, in order to measure and detect the layer thickness or a value dependent on the layer thickness. During strip transportation, the strip runs past the layer thickness sensor so that layer thickness values, in particular layer thicknesses, are determined sequentially or continuously along the strip length. The measured values can then be used to make changes in the layer thickness for one-off, repeated or continuous adjustment, preferably a regulation, of the strip positioning. For example, if there is a deviation of a measured thickness from a target thickness or a relative change in the layer thickness beyond a certain amount, a regulating adjustment or regulation of the strip positioning can take place. Alternatively or additionally, an adjustment of the coating can also be performed by changing an activation of the device for vapor deposition, which is preferably coupled to the layer thickness sensor via a corresponding coating controller for this purpose. It is particularly preferred if the layer thickness sensor is designed as an X-ray fluorescence sensor since such a sensor can be obtained inexpensively and can be operated with little effort and low maintenance, whereby it ensures a sufficiently high detection accuracy.

In a further development, the layer thickness sensor is positioned to move in a traversing manner, for example be arranged on the coating chamber, and can be moved by means of a layer thickness sensor adjustment mechanism. The layer thickness sensor adjustment mechanism can, for example, be designed vacuum-compatible and can be arranged within the coating chamber. The layer thickness sensor adjustment mechanism can, for example, be electrical or pneumatic. Alternatively, the layer thickness sensor adjustment mechanism can be arranged outside the coating chamber and can be coupled into the coating chamber via a feedthrough, for example by means of bellows. The layer thickness sensor adjustment mechanism is preferably provided with a motor for the set and/or regulated control of the position of the layer thickness sensor in the transverse direction of the strip. The mentioned traversingly mobile arrangement of the coating thickness sensor on the coating system serves the purpose of detecting layer thickness values which contain information about the layer thickness profile of the coated strip in the transverse direction of the strip. As a result, deviations of the layer thickness profile from a desired or an expected layer thickness profile can be detected, and they can be used for drawing conclusions about any unplanned properties of the strip positioning, in particular for example a formation of a transverse arc in the strip, and/or an inhomogeneity in the application of the material vapor on the strip by the device for vapor deposition as a result of possible inhomogeneities in the material vapor emerging from the nozzle outlet.

Alternatively or additionally, a developed embodiment of the coating system can have a distance sensor. Such a sensor can then be used to detect a change in the distance from the sensor and therefore a change in the strip run that may occur, for example caused by fluctuations in strip tension. Knowing the measured values obtained by the distance sensor, an improvement in the homogeneity of the applied coating can then be brought about by adjusting the coating system, in particular by readjusting the strip positioning by means of the strip positioning assembly. For example an inductive distance sensor or a capacitive distance sensor, as are familiar to a person skilled in the art, can serve as a distance sensor.

If a distance sensor is present, it will be positioned in such a way that the distance of a region of the strip running behind the strip positioning assembly when viewed in the strip transport direction is detected. Preferably, the distance sensor is positioned in front of the coating zone so that a distance of a region of the strip running in front of the coating zone viewed in the strip transport direction is detected. This has the advantage that the distance is measured in a region located comparatively close to the strip positioning assembly, as a result of which the conditions are met for a particularly exact adjustment or regulation of the strip positioning assembly as a function of the distance.

If a layer thickness sensor is present, it will be positioned such that the layer thickness is detected of a coating of a region of the strip running behind the coating zone when viewed in the strip transport direction.

In a preferred development, it is provided that the distance sensor is movably positioned in a traversing manner, for example arranged in the coating chamber, and is designed to be movable on the coating system by means of a distance sensor adjustment mechanism. Similar to the above explanations in connection with the traversing movement of the layer thickness sensor, the distance sensor can then not only track distance information at a fixed position of the transverse direction of the strip and for changing longitudinal positions, but distance information can be detected along at least a section of the transverse direction of the strip, preferably the entire transverse direction of the strip, and transverse direction positioning-dependent distance profiles or a change of distance profiles can therefore be detected. This embodiment has the advantage that, starting from the information obtained in this way, a correction of the strip positioning can be made in a particularly advantageous manner, and the homogeneity of the coating can thereby be improved.

According to one development, the layer thickness sensor, if present, and/or the distance sensor, if present, is coupled to the strip positioning assembly via a control unit. The control unit is configured to read out values of the respective sensor or sensors, i.e. to read out layer thickness values and/or distance values, and to control the strip positioning arrangement in order to adjust, preferably regulate, strip positioning as a function of detected layer thickness values and/or distance values. This means that the coating system has a control unit which receives data from the layer thickness sensor and/or the distance sensor (depending on which of these sensors is present or which of these sensors are present) and is able to control the strip positioning assembly on the basis of these transmitted values in order to adjust the strip positioning. The strip positioning can be adjusted in particular by moving the guide roller which can be moved in the direction perpendicular to the strip surface. For example, it is possible to move the guide roller, which can be moved in the direction perpendicular to the strip surface, towards the strip in order to generate an increasing force and, with increasing movement towards the strip, also a corresponding deflection of the strip, and consequently to cause a reduction in any transverse arc that may be present. The corresponding device of the control unit can be implemented, for example, in such a way that empirically obtained data records are stored on the control unit, which link a dependence between the position of the guide roller movable in the vertical direction toward the strip surface on the one hand and a change in the transverse arc with changing the position of this guide roller on the other hand. Alternatively, however, it can also be simply provided that the control unit is capable of implementing a control loop on the basis of corresponding program sequences which works with layer thickness and/or distance as the controlled variable and, after detection of a deviation of the controlled variable from the corresponding setpoint, causes a change in the position of the guide roller movable in the direction perpendicular to the strip surface and, on the basis of the controlled variable which is then redetected, determines whether a further change in the position of the guide roller movable in the direction perpendicular to the strip surface is then required, and how this will be carried out. In other words, a further development is provided as a coating system in which the change in the position of the movable roller of the strip positioning assembly is the manipulated variable for controlling the controlled variable selected as the layer thickness and/or distance.

In order to be able to bring about an adjustment of the transverse arc, preferably a regulation of the transverse arc, the coating system preferably has the above-mentioned traversingly movable layer thickness sensor in order to carry out the control, preferably regulation, starting from determined layer thickness profiles. As an alternative to a traversingly movable layer thickness sensor, a number of two or more layer thickness sensors, preferably at least three layer thickness sensors, can also be present which are arranged at a suitable longitudinal position of the strip located behind the coating zone such that they point to different, for example equidistant, positions of the transverse direction of the strip. This embodiment ensures that a layer thickness profile is obtained without the requirement of a traversing layer thickness sensor.

Alternatively or additionally, it can be provided that the axis of rotation of the first guide roller and the axis of rotation of the second guide roller are coupled to one another in a rotationally fixed manner via a mechanical connection, i.e. both have a constant angle to one another and are preferably oriented parallel to one another, but the mechanical connection itself is pivotably mounted, wherein the pivoting preferably takes place in a pivot axis parallel to the strip transport direction. In such an embodiment, the strip positioning assembly, i.e. the first guide roller and the second guide roller, can therefore be pivoted together about the pivot axis with their orientation to each other remaining unchanged with respect to their angle to each other. The pivoting takes place, for example, by means of a pivoting device coupled to the strip positioning assembly which can be formed as a whole, for example, from an adjustment unit and a coupling element, for example a connecting rod, between the adjustment unit and the strip positioning assembly. The adjustment unit engages, for example, in the mechanical connection with which the first guide roller and the second guide roller are connected to each other at a position on the side of the strip which is further away from the pivot axis, so that the pivoting of the first guide roller and the second guide roller is brought about by adjusting the adjustment unit which is designed, for example, as a lifting rod. The adjustment unit for the rotary movement can, for example, be designed to be vacuum-compatible and arranged inside the coating chamber; alternatively, however, an arrangement provided outside the sealing chamber is also possible. The adjustment unit is preferably designed to be pneumatic or electrical as an electric motor. By means of a pivotable assembly of the strip positioning assembly with a joint pivoting of the rotational axes oriented rotationally fixed relative to one another, the advantage is achieved that any deviations of the strip position from the ideal of a strip center position can be corrected. As a result, improvements of a layer homogeneity, in particular in the layer thickness distribution, are directly achieved.

In the context of the present description, the strip position refers to the lateral-face section of the guide roller, viewed in the direction of the axis of rotation, on which the strip is conveyed. When the strip positioning assembly is pivoted, the strip position is corrected towards a desired section. It is preferably desirable for the strip to be guided either centered on the lateral-face section of at least one, preferably all, non-pivotable rollers of the strip run; such a case is referred to as the preferably desired case of the strip center position in the context of the present description.

Particularly preferred is an embodiment in which both the axis of rotation of at least one of the two guide rollers at the point of contact of the strip with the guide roller is movable in a direction perpendicular to the strip surface, or in a direction with a directional component perpendicular to the strip surface relative to the other guide roller, and the strip positioning assembly is pivotally mounted. Such a constellation leads to the further advantage that the same device allows not only the transverse curvature to be prevented or largely prevented, but also the extensive or complete maintenance of the strip center position to be achievable.

Particularly preferably, if the coating system is pivotable with the coating chamber and has guide roller axes of rotation coupled to one another in a rotationally fixed manner, it will also have an optical strip position sensor which is arranged downstream from the strip positioning assembly in the strip transport direction and coupled to the pivoting device via a control device. The control device is prepared to control the pivoting device for adjusting, preferably for regulating, the strip position by pivoting the strip positioning assembly as a function of a sensor signal from the strip position sensor. For example, this can be implemented by storing empirically acquired data in a memory area of the control device, which assigns a pivoting movement to be performed to a sensor-detected deviation of a strip position from the strip center position and also performs this by activating, for example, a corresponding available motor such as an electric motor. The control unit for adjusting, preferably for regulating, the pivoting of the strip positioning assembly for bringing about or approaching the strip position towards the strip center position can be implemented as a separate second control unit independently of the already mentioned control unit for controlling the relative position of the guide rollers to one another, but the control device can also be a separate memory area of this already mentioned control unit.

The device for vapor deposition of the material is preferably a jet vapor deposition device.

A person skilled in the art understands the term jet vapor deposition device to be a device in which the coating material is brought into the gas phase thermally, for example in a crucible, and it is then transported to the substrate—typically in a gas stream together with a carrier gas stream of inert gas, but in some embodiments also as a gas stream consisting exclusively of the material brought into the gas phase—preferably at a gas stream speed above the speed of sound, particularly preferably above 500 m/s. The mode of operation is found, for example, in the review article in the Handbook of Deposition Technologies for Films and Coatings Science, Applications and Technology, 2010, pp. 881-901, https://doi.org/10.1016/6978-0-8155-2031-3.00018-1 (linked on the filing date).

The surface to be coated is usually in an atmosphere which has a negative pressure relative to the atmosphere prevailing in the crucible. The surface to be coated is, for example, in a technical vacuum with a pressure preferably less than 100 mbar, for example between 10⁽⁻³⁾ mbar and 20 mbar which, in large-scale implementation, is a good compromise between good properties of the coating and the effort expended to create and maintain the vacuum.

The JVD method reveals its advantages in particular in the large-area coating of strips, in particular also of strip metal such as strip steel, for example. An advantage of JVD is that, due to the comparatively high pressure with which the material present in the gas phase is directed toward the surface to be evaporated, a coating of the strip at a high coating rate is possible which, for example, with correspondingly high selected strip speeds, brings the advantage of good economical strip coating.

In an alternative preferred development, the device for vapor deposition of the material is formed with an evaporation section which has a pre-evaporation section and a post-evaporation section, preferably designed as a crucible, wherein the pre-evaporation section has a spray head for preparing the coating material present as starting material and an injector tube. The injector tube is designed to guide the coating material prepared in the spray head to the post-evaporation section and to bring the prepared coating material into the post-evaporation section in order to convert it into the gas phase there.

The spray head is preferably a wire sprayer for the arc melting and/or arc evaporation of the starting material introduced into the wire sprayer. The material used to form the respective coating is, for example, in wire or strip form. The starting material is brought into the sphere of influence of an electric arc, wherein preferably two wires or two strips of the starting material are present, one of which is connected as a cathode and one of which is connected as an anode to a DC electric voltage source, and a voltage sufficient to form an arc is set with the DC voltage source. The material melted and/or evaporated using the energy of the arc flows by means of a gas flow from a gas or a gas mixture through an inlet into the interior of a chamber, the so-called crucible, is heated to a temperature at least equal to the evaporation temperature of the at least one material used for coating, or the material having the highest evaporation temperature. In this case, the material(s) in the crucible are completely evaporated and/or exit through an opening in the crucible. The evaporated material(s) contact(s) the surface to be coated of the component of the strip-shaped material or workpiece to form the respective coating.

The post-evaporation section preferably includes a nozzle section coupled thereto, which has the nozzle outlet and ends with it.

In a special case when correspondingly high exit speeds of the material exiting the post-evaporation section are achieved, this alternative embodiment may be considered a variant of JVD.

One concept of the invention relates to a method for coating a strip with a coating system. The method can be carried out, for example, with a coating system of the type mentioned at the outset or one of its developments. The method comprises at least the steps mentioned below:

A strip is transported through a coating zone of the coating system in which a strip surface of the strip is then coated.

During the coating, one of the following parameters is determined repeatedly or continuously:
a) a layer thickness value by means of a layer thickness sensor, wherein the layer thickness value can be, for example, a layer thickness or a layer thickness profile.
b) a distance value by means of a distance sensor, wherein the distance value can, for example, be a distance or a distance profile.

The parameter is continuously compared with a setpoint. The setpoint can be, for example, a comparison value or a comparison curve or a parameter set of curves.

When the at least one parameter deviates from the setpoint by more than a tolerated deviation, activating the strip positioning assembly in order to adjust the transverse arc of the strip, wherein the strip positioning assembly comprises at least a first guide roller arranged on the first side of the strip and a second guide roller arranged on the second side of the strip, and wherein the first guide roller and the second guide roller are positioned in such a way that both the first guide roller and the second guide roller are in contact with the strip during transportation of the strip, and wherein one of the two guide rollers is movable in a direction perpendicular to the strip surface at the point of contact of the strip with the guide roller,

optionally: repeating the previous two steps until the setpoint is reached in a controlled manner, or a value is reached that deviates from the setpoint by less than a tolerated deviation, but by no more than the tolerated deviation, for the controlled adjustment of the transverse arc of the belt.

The control or regulation of the transverse arc by changing the position of the first movable guide roller reveals its advantages in a special way when the determination of the coating thickness is used as a controlled variable, which is why a coating system with a coating thickness sensor and a method for coating using the layer thickness as a controlled variable are particularly preferred embodiments of the present developments.

In a preferred further development of the method, a strip position of the strip is also determined by means of an existing strip position sensor and, if the strip position deviates from a setpoint value, preferably the strip center position, by more than a tolerated deviation, a pivoting device is activated to adjust the strip position of the strip by pivoting the guide rollers of the strip positioning assembly, which are coupled to the coating chamber so that they can be pivoted relative to one another in a rotationally fixed manner about a common pivot point. It is preferred if the strip position reaches its strip center position. In this preferred development, the correction of the strip transport comprises or consists at least of not only reducing or eliminating transverse arcs but also displacing the strip position towards the strip center position.

The layer thickness sensor is preferably arranged behind the coating zone as viewed from the transport direction of the strip, the distance sensor and/or the strip position sensor being preferably arranged behind the strip positioning assembly but in front of the coating zone.

Preferably, activation is based on empirically determined reference values that are stored in a control unit that is coupled not only to the mentioned sensors but also to the belt positioning assembly.

Alternatively or additionally, the transverse arc and/or the strip position are controlled with the layer thickness, and/or with distance, and/or with the strip position as the controlled variable.

Further details, features, and advantages of the subject-matter of the invention result from the following description in connection with the drawings, which show embodiments of the invention by way of example.

It goes without saying that the features mentioned above and below can be used not only in the combination indicated but also in other combinations or in isolation.

In the drawings:

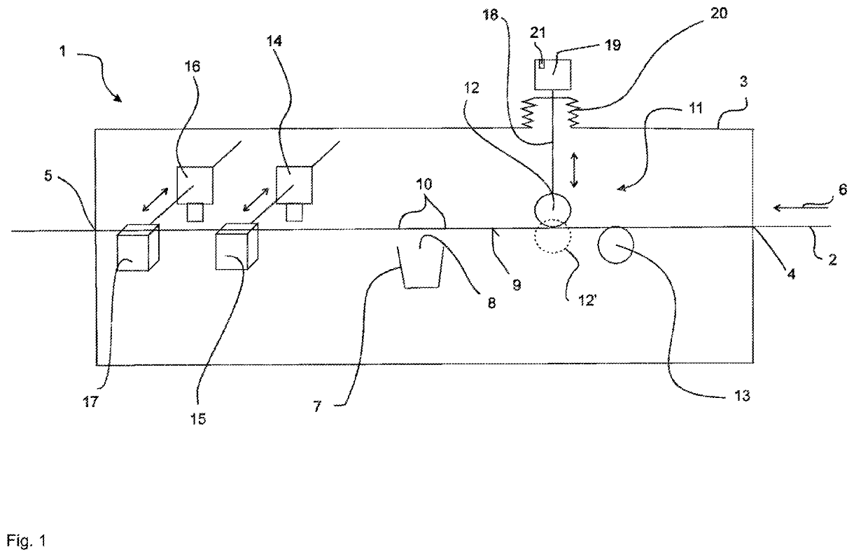

FIG. 1: shows a schematic representation of an embodiment of a coating system according to the invention in a side view;

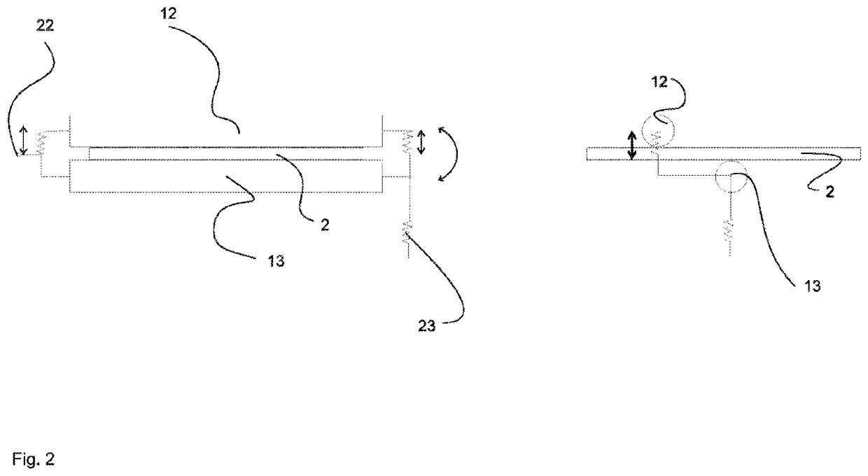

FIG. 2: shows a schematic representation of a strip positioning assembly of the coating system in the development of the embodiment of FIG. 1 with the strip transport direction as the viewing direction (a) and in a side view (b);

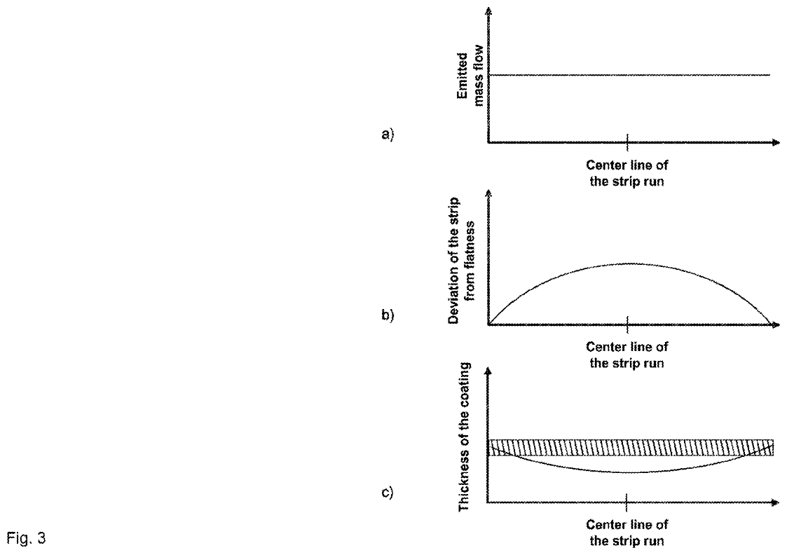

FIGS. 3 to 6: show a representation of the layer thickness distribution in order to illustrate the correction of the strip positioning by means of a strip positioning assembly.

In FIG. 1, a schematic representation of an embodiment of a coating system 1 according to the invention can be seen in a side view. The coating system 1 serves to coat a strip 2. For this purpose, the system has a coating chamber 3 with a chamber inlet 4 and a chamber outlet 5. The strip is transported through the chamber along the arrow 6 shown. Preferably another coating channel, not shown in more detail in FIG. 1, is arranged inside the chamber and has heating means designed, for example, as heating coils, through which the strip 2 runs. The strip runs past a device 7 arranged in the coating chamber for the vapor deposition of the material. This has a nozzle outlet 8 which is oriented towards the strip surface 9 to be coated. During coating, material vapor in a coating zone 10 contacts the strip 2, which passes through the coating zone 10, and forms a coating there as a result of condensation. In principle, it is also possible that sections of the device 7 for vapor deposition of the material are positioned outside the coating chamber 3 as long as the nozzle outlet 8 opens within the coating chamber.

Viewed in the strip transport direction 6, a strip positioning assembly 11 is arranged in front of the coating zone 10. On the first side of the strip, the strip positioning assembly 11 has a first guide roller 12. A second guide roller 13 is arranged on the second side of the strip. The first guide roller and the second guide roller are positioned such that, during transportation of the strip 2, both the first guide roller 12 and the second guide roller 13 are in contact with the strip 2.

In the embodiment shown, the axis of rotation of the second guide roller 13 is fixed, which means that it does not change its position relative to the coating chamber. The first guide roller 12 is movable at the contact location of the strip in the direction perpendicular to the strip surface, and it can therefore be moved, for example, in the direction of the position indicated by the circle 12′ which would cause a deflection of the strip. For the movement, the guide roller 12 is coupled via a suspension 18 to an electromechanically activatable mechanism 19, wherein the coupling is vacuum-tight due to a bellows 20.

Seen in the strip transport direction behind the coating zone, a layer thickness sensor 14 and a distance sensor 16 are arranged which are movable in a traversing manner by a corresponding layer thickness sensor adjustment mechanism 15 and a distance sensor adjustment mechanism 17 in the transverse direction of the strip.

The layer thickness sensor 14 and the distance sensor 16 are coupled via a control unit 21 to the strip positioning assembly 11, more precisely to the electromechanically activatable mechanism 19 of the strip positioning assembly 11.

FIGS. 2a and 2b reveal a developed embodiment according to which the axes of rotation of the two guide rollers 12, 13 are coupled in a rotationally fixed manner relative to one another about a common pivot point 22 so as to be pivotable with the coating chamber for changing a strip position of the strip 2 by means of an adjusting unit 23 of a pivoting device. The pivoting device can be designed, for example, as the entirety of a movable suspension and an adjustment unit 23, which is not shown in detail here.

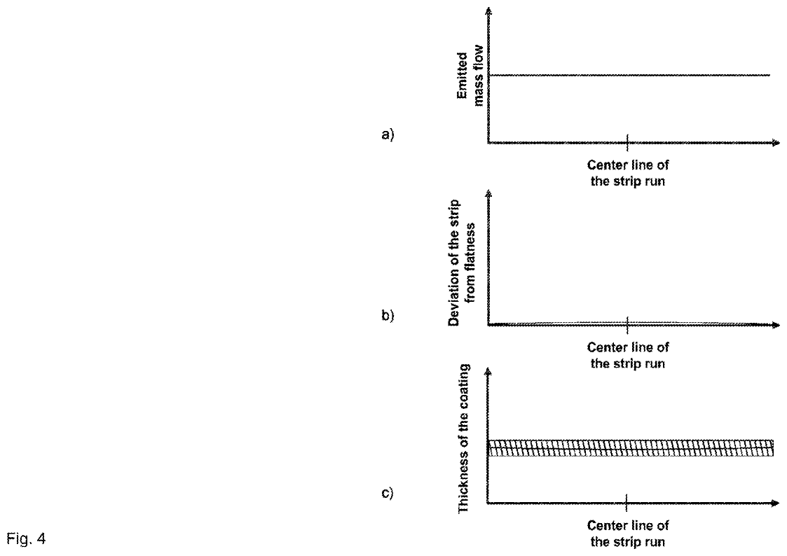

FIG. 3 shows by way of example how a coating system of FIG. 1 can be used in an advantageous manner. The strip, when the mass flow of the material vapor is homogeneous in the transverse direction of the strip, exhibits a strip deviation from the flat position in the transverse direction of the strip, i.e. a transverse arc, which in the related example results in a greater distance from the nozzle outlet in the center of the strip than at the edges of the strip. As shown in FIG. 3c, this leads to a layer thickness inhomogeneity outside the tolerance strip, which is the totality of possible setpoint values (dashed region). By activating the roller 12 to move itself in the direction toward the strip, the transverse arc is largely eliminated due to the force exerted by the guide roller 12 on the strip (see FIG. 4b). The result is a layer thickness distribution within the tolerance strip (see FIG. 4c).

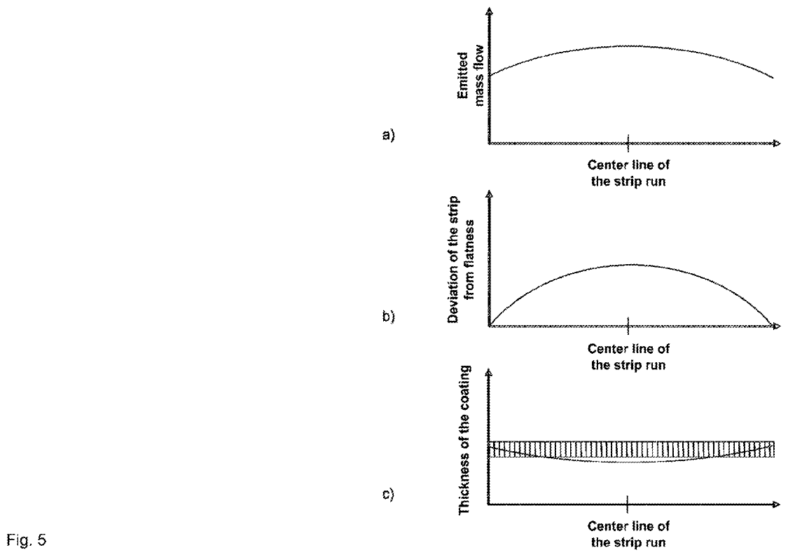

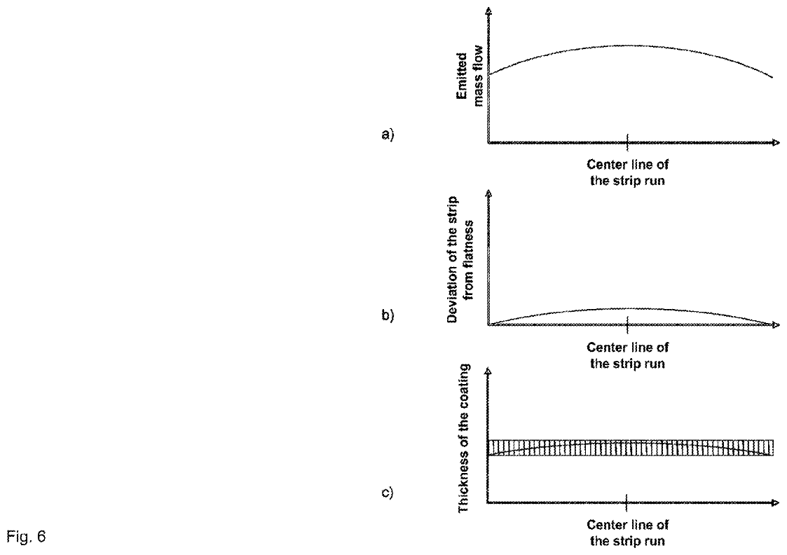

FIG. 5 shows a constellation comparable to FIG. 3, wherein FIG. 5a reveals that, in contrast to the constellation shown in FIG. 3a, there is an inhomogeneous distribution of the mass flow. The effect of the inhomogeneity of the mass flow due to uneven distribution of the material vapor overlaps with the effect of the transverse arc. It can be seen in FIG. 6 that achieving a homogeneous coating (FIG. 6c) in this case is only possible when a certain amount of transverse arc is maintained (FIG. 6b). From this, the conclusion can be drawn that the control or regulation of the change in the flat position by changing the position of the first guide roller 12 reveals its advantages in a special way when the determination of the layer thickness is used as a controlled variable. A coating system with a layer thickness sensor and a method for coating with the layer thickness as a controlled variable therefore represent particularly preferred embodiments of the present development.

1. A coating system for coating a metal strip with a material in a gas phase, the coating system comprising:
a coating chamber having a chamber inlet and a chamber outlet for transporting the strip through the coating chamber,
a device for vapor deposition of the material with an evaporation section for evaporating the material into the gas phase, and having a nozzle section for guiding the material in the gas phase to a nozzle outlet of the nozzle section that opens within the coating chamber, for discharging the material in the gaseous phase towards the strip in the direction of a strip surface of the strip to be coated, in order to continuously contact the strip surface to be coated with material in the gaseous phase in a coating zone through which the strip is transported, and to form a coating on the strip surface by condensation, and
a strip positioning assembly, which is arranged in front of the coating zone as seen in a strip transport direction, for continuous correction of strip transportation, wherein the strip positioning assembly has at least one first guide roller arranged on a first side of the strip and a second guide roller arranged on a second side of the strip, wherein the first guide roller and the second guide roller are positioned such that both the first guide roller and the second guide roller are in contact with the strip when the strip is transported.

2. The coating system according to claim 1, wherein the first guide roller and the second guide roller are spaced apart from one another in the strip transport direction.

3. The coating system according to claim 1, wherein the strip positioning assembly is positioned directly before the coating zone.

4. The coating assembly according to claim 1,
wherein an axis of rotation of one of the two guide rollers is fixed or is configured to be continuously fixed during strip transport, and
an axis of rotation of the other of the two guide rollers at a point of contact of the strip with the other guide roller is movable in a direction perpendicular to the strip surface, or in a direction with a directional component perpendicular to the strip surface.

5. The coating system according to claim 1, wherein, viewed in the strip transport direction, a layer thickness sensor is positioned behind the coating zone for the contactless determination of layer thickness values of the coating.

6. The coating system according to claim 5, wherein the coating thickness sensor is movably positioned in a traversing manner, and is movable by means of a coating thickness sensor adjustment mechanism for determining coating thickness values formed as a coating thickness profile.

7. The coating system according to claim 1, further comprising a distance sensor for determining distance values of the strip, which distance sensor is positioned in front of the coating zone viewed in the strip transport direction.

8. The coating system according to claim 7, wherein the distance sensor is movably positioned in a traversing manner, and is movable by means of a distance sensor adjustment mechanism.

9. The coating system according to claim 1, further comprising a layer thickness sensor positioned behind the coating zone for the contactless determination of layer thickness values of the coating and a distance sensor for determining distance values of the strip, which distance sensor is positioned in front of the coating zone viewed in the strip transport direction, wherein the layer thickness sensor and/or the distance sensor is coupled to the strip positioning assembly via a control unit, and the control unit is configured to activate the strip positioning assembly in order to adjust strip positioning as a function of detected layer thickness values and/or distance values.

10. The coating system according to claim 1, wherein respective axes of rotation of the two guide rollers are coupled in a rotationally fixed manner relative to one another about a common pivot point so as to be pivotably coupled to the coating chamber for changing a strip position of the strip.

11. The coating system according to claim 10, further comprising an optical strip position sensor which is arranged downstream of the strip positioning assembly in the strip transport direction, and which is coupled via a control device to a pivoting device coupled to the strip positioning assembly, wherein the control device is configured to activate the pivoting device in order to adjust the strip position as a function of the sensor signal of the strip position sensor.

12. The coating system according to claim 1, wherein:
the device for vapor deposition of the material is a jet vapor deposition device, or
the device for vapor deposition of the material is formed with the evaporation section having a pre-evaporation section and a post-evaporation section formed as crucible,
wherein the pre-evaporation section has a spray head for preparing the coating material present as a starting material and an injector tube, wherein the injector tube is designed to conduct the coating material processed in the spray head to the post-evaporation section and is coupled to the post-evaporation section for guiding the processed coating material into the post-evaporation section for converting the processed coating material into the gas phase therein,
wherein the spray head is a wire sprayer for arc melting and/or arc evaporation of the starting material introduced into the wire sprayer,
wherein the coating rate is adjusted by a feed rate of feeding starting material into the spray head.

13. A method for coating a strip with a coating system according to claim 1, comprising:
transporting the strip through the coating zone of the coating system for coating the strip surface,
i) repeatedly or continuously determining at least one of the following parameters:
a) a layer thickness value by means of a layer thickness sensor,
b) a distance value by means of a distance sensor;
ii) continuously comparing the parameter to a target value; and
iii) when the at least one parameter deviates from a setpoint by more than a tolerated deviation, activating the strip positioning assembly to adjust a transverse arc of the strip, wherein the strip positioning assembly has at least one first guide roller arranged on a first side of the strip and a second guide roller arranged on a second side of the strip, wherein the first guide roller and the second guide roller are positioned in such a way that both the first guide roller and the second guide roller are in contact with the strip during transport of the strip, and wherein one of the two guide rollers is movable in a direction perpendicular to the strip surface at a point of contact of the strip with the guide roller.

14. The method according to claim 13, wherein a strip position of the strip is additionally determined by means of a strip position sensor and, when the strip position deviates from a target value by more than a tolerated deviation, a pivot device coupled to the strip positioning assembly is activated for adjusting the strip position of the strip by pivoting the guide rollers of the strip positioning assembly which are rotationally fixed relative to one another and can be pivotably coupled to the coating chamber about a common pivot point.

15. The method according to claim 13, wherein the activation is performed on the basis of empirically determined reference values which are stored in the control unit.

16. The coating system according to claim 3, wherein the strip positioning assembly is positioned less than 11 meters away from the coating zone.

17. The coating system according to claim 5, wherein the layer thickness sensor is an X-ray fluorescence sensor.

18. The coating system according to claim 6, wherein the coating thickness sensor is movably positioned in the coating chamber.

19. The coating system according to claim 7, wherein the distance sensor is an inductive or capacitive sensor.

20. The method according to claim 13, further comprising:
repeating steps ii) and iii) until the setpoint is reached in a controlled manner, or a value is reached that deviates from the setpoint by less than a tolerated deviation, but by no more than the tolerated deviation, for the controlled adjustment of the transverse arc of the belt.
